(19) United States
(12) Patent Application Publication
(10) Pub. No.: US 2008/0121515 A1
(43) Pub. Date: May 29, 2008

(54) Magnetron sputtering utilizing halbach magnet arrays

(75) Inventor: Paul S. McLeod, Berkeley, CA (US)

Correspondence Address: SEAGATE TECHNOLOGY LLC;c/o MCDERMOTT WILL & EMERY LLP, 600 13TH STREET, NW, WASHINGTON, DC, 20005-3096, US

(73) Assignee: SEAGATE TECHNOLOGY LLC

(21) Appl. No.: 11/604,326

(22) Filed: Nov. 27, 2006

(51) Int. Cl. C23C 14/35

(52) U.S. Cl. 204/192.12; 204/298.16; 204/298.12

(57) ABSTRACT

A magnetron sputtering target assembly, comprises a target adapted to comprise of at least one material to be sputtered, the target including a pair of oppositely facing surfaces; and a magnet assembly comprising a plurality of Halbach magnet arrays adjacent one of the surfaces for providing magnetic field lines which emerge from and re-enter the other of the surfaces to form an arched, closed-loop magnetic field path over the other surface. The enhanced magnetic flux intensity provided by the Halbach magnet assemblies, relative to conventional magnetron magnet assemblies, facilitates sputtering of thick targets comprised of magnetic materials in the manufacture of recording media, as well as low pressure sputtering of high quality carbon-containing protective overcoat materials for such media.

### FIELD OF THE INVENTION

The present invention relates to improved magnetron sputtering cathodes and sputter processing utilizing Halbach magnet arrays providing increased magnetic field intensities over the sputtering surface of the cathode/target. The invention is useful in the sputtering of thick targets and targets comprised of magnetic materials and enjoys particular utility in the fabrication of magnetic and magneto-optical (MO) recording media.

### BACKGROUND OF THE INVENTION

Cathode sputtering is widely utilized for depositing thin films of a variety of materials onto substrates, and is of particular importance in the manufacture of integrated circuit semiconductor devices and various types of thin film-based recording media, e.g., magnetic and magneto-optical (MO) media, as well as CD and DVD-based media. The sputter deposition process involves vaporizing (sputtering) the material to be deposited by ion bombardment of the surface of a target comprised of the material, the target forming part of a cathode assembly located in an evacuated chamber containing an inert gas, e.g., argon (Ar). A high voltage electric field is applied between the negatively charged cathode assembly and a positively charged anode electrode. A plasma is formed within the chamber, comprising positively charged ions of the inert gas formed by collision of atoms of the gas with electrons emanating from the cathode surface. The positively charged ions of the inert gas are attracted to the negatively charged cathode (i.e., target) surface, whereby particles of the target material are dislodged (ejected) when the ions strike the target surface. The ejected (i.e., sputtered) particles traverse the interior space of the chamber and deposit as a thin film on the surface(s) of at least one substrate (workpiece) positioned on a support within the chamber.

Although the sputtering process can be performed solely by means of the electric field established between the negatively charged cathode and positively charged anode electrodes, substantially increased deposition rates are possible by utilization of a magnetic field in combination with the electric field, as in “magnetron” sputtering, in which an arched magnetic field, formed in a closed loop over the surface of the sputtering target, is superimposed on the electric field. More specifically, in magnetron sputtering a magnet assembly comprised of a plurality permanent or electromagnets is provided behind the sputtering surface of the target, such that magnetic flux lines from the magnet assembly extend from a first pole of the assembly through the target, and emerge, extend, and return through the target to a second pole of the magnet assembly, thereby forming a virtual “tunnel”. When the magnet assembly forms an arched, closed-loop magnetic field or “racetrack” electrons from the plasma are advantageously trapped or confined plasma in an annular region adjacent the target surface. The trapped or confined electrons are swept about the closed loop racetrack under the combined influences of the electric and magnetic fields. As a consequence of the electron trapping and motion within the racetrack, the number of collisions between electrons and inert gas atoms to produce positively charged ions available for bombardment, hence sputtering of the target surface, is greatly increased in the regions defined by the arched, closed-loop magnetic field.

A number of differently magnetron sputtering cathode configurations are presently known, including, inter alia, planar-, cylindrical-, and conical-shaped targets. Referring to FIG. 1, shown therein, in simplified, schematic perspective view, is a sectioned portion of a conventional planar magnetron sputtering cathode assembly 10 comprising an elongated planar sputtering target 1 with an upper, sputtering surface 2 and a lower surface 3, a magnet assembly 4 having an upper end 5 adjacent the lower surface 3 of target 1, a lower end 6, and a magnetic shunt plate 7 in contact with the lower end 6 of magnet assembly 4. Reference numeral 8 indicates a first lateral end of assembly 10 and reference numeral 9 indicates a sectioned end of assembly 10. Not shown in the figure is the second lateral end of assembly 10, similar in essential respect to first lateral end 8. Also not shown in the figure (for illustrative simplicity) is conventional structure for mounting and maintaining target 1 in fixed position relative to magnet assembly 4, e.g., an underlying mounting plate and/or edge-mounted brackets and flanges.

As shown, magnet assembly 4 comprises a plurality of unidirectionally polarized magnets arranged in linear fashion, each with polarity oriented toward (i.e., upwardly) or away (i.e., downwardly) from sputtering target 1, as indicated by arrows where possible. In the figure, Θ=magnet polarity oriented toward sputtering target 1 and X=magnet polarity oriented away from sputtering target 1. At portions of assembly 10 other than the first and second lateral ends, e.g., the portion adjacent to sectioned end 9 of assembly 10 and portions extending toward first lateral end 8, magnet assembly 4 comprises a plurality of centrally positioned magnets 4_{C} with downwardly oriented polarity and laterally positioned left and right magnets 4_{L} and 4_{R}, respectively, with upwardly oriented polarity. As shown by the arrows F_{L} and F_{R} in the figure for the set of magnets adjacent sectioned end 9, magnetic flux from the laterally positioned magnets 4_{L} and 4_{R} emerges from target 1 proximate the lateral edges thereof, arches over the upper, sputtering surface 2 of the target, and re-enters the target at the central portion thereof via the centrally positioned magnets 4_{C}. A similar flux pattern (not shown in the figure for illustrative simplicity) results for each of the other sets of magnets, except for the magnet set at the first lateral end 8. Magnetic shunt plate 7 is provided for preventing sputtering at the lower end 6 of magnet assembly 4. At the first and second lateral ends of assembly 10, e.g., as illustrated at first lateral end 8, magnet assembly 4 comprises a centrally positioned magnet 4_{C} and a pair of laterally positioned magnets 4_{L} and 4_{R}, each with upwardly oriented polarity for providing 180° redirection of electrons confined to the arched flux regions, as shown by arrow 11, thereby forming the characteristic oval-shaped “racetrack” of planar magnetron target/cathode assemblies, as for example, schematically shown in perspective in FIG. 2.

Adverting to FIG. 3, shown therein, in simplified, schematic cross-sectional view, is a portion of conventional cylindrical magnetron sputtering cathode assembly 20 comprising an elongated cylindrical-shaped sputtering target 21 with an outer, sputtering surface 22 and an inner surface 23, a magnet assembly 24 positioned adjacent inner surface 22 and having an upper end 25 adjacent the inner surface 23 of target 21, a lower end 26, and a magnetic shunt plate 27 in contact with the lower end 26 of magnet assembly 24. As with the planar magnetron assembly 10 shown in FIG. 1, magnet assembly 24 similarly comprises a plurality of centrally positioned magnets 24_{C} with downwardly oriented polarity and pairs of laterally positioned magnets 24_{L} and 24_{R} with upwardly oriented polarity. As shown by the heavy arrows F_{L} and F_{R} in the figure, magnetic flux from the laterally positioned magnets 24_{L} and 24_{R} emerges from target 21, arches over the outer, sputtering surface 22 of the cylindrically shaped target, and re-enters the target at the central portion thereof via centrally positioned magnet 24_{C}. As with magnet assembly 4 shown in FIG. 1, magnet assembly 24 is provided at the lateral ends thereof with a centrally positioned magnet 24_{C} and a pair of laterally positioned magnets 24_{L} and 24_{R}, each with upwardly oriented polarity for providing 180° redirection of electrons confined to the arched flux regions. Not shown in the figure, for illustrative simplicity, is conventional structure for mounting and rotating cylindrical target 21.

In operation of cylindrical magnetron sputtering cathode assembly 20, the magnet assembly 24 is maintained stationary while the cylindrical sputtering target 21 is rotated about its axis, thereby facilitating substantially full utilization (i.e., erosion by sputtering) of sputtering surface 22. In this regard, cylindrical magnetron sputtering cathodes are advantageous vis-à-vis planar magnetron sputtering cathodes, where erosion (via sputtering) is generally limited to the target surface beneath the arch-shaped racetrack or tunnel regions.

Typically, approximately one-half of the magnetic flux provided by the magnets of conventional magnetron magnet assemblies (hereinafter referred to as the “pass through flux” or “PTF”) passes through and over the target surface, whereas approximately one-half of the magnetic flux passes through the magnetic shunt plate adjacent the lower end of the magnet assembly. However, the substantial loss of PTF associated with conventional magnetron magnet assemblies can be disadvantageous/problematic in many sputter deposition applications. Specifically:

1. when sputtering magnetically soft materials, the use of thick targets further limits the PFT, thereby adversely affecting or preventing creation of an emergent magnetic field sufficient to initiate plasma discharge even at low gas pressures;

2. when performing reactive sputtering of metal targets with low PTF, as by addition of reactive gas(es) to the inert sputtering gas atmosphere, a low density ion flux is produced at the target surface which can, in some instances, allow formation of surface compounds which can reduce the sputtering rate to effectively zero; and

3. when sputtering targets comprised of certain materials, e.g., carbon (C), a low PTF can prevent establishment of plasma discharge at low gas pressure. However, carbon films which are optimal for use as protective overcoats in the manufacture of magnetic and magneto-optical (MO) recording media in disk form require formation at low gas pressures.

In view of the foregoing, there exists a clear need for improved magnetron sputtering cathode/target assemblies which provide increased PTF for facilitating sputter deposition of a variety of materials requiring adequate magnetic flux for plasma generation, maintenance of target surface composition, and formation of films with desired and/or optimum characteristics.

### DISCLOSURE OF THE INVENTION

An advantage of the present invention is an improved magnetron sputtering target assembly.

Another advantage of the present invention is an improved method of performing magnetron sputtering of target materials.

Yet another advantage of the present invention is an improved method of performing magnetron sputtering of target materials utilized in the manufacture of thin film magnetic and magneto-optical (MO) recording media.

Additional advantages and other features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to an aspect of the present invention, the foregoing and other advantages are obtained in part by an improved magnetron sputtering target assembly, comprising:

(a) a target adapted to comprise at least one material to be sputtered, the target including a pair of oppositely facing surfaces; and

(b) a magnet assembly comprising a plurality of Halbach magnet arrays adjacent one of the surfaces for providing magnetic field lines which emerge from an re-enter the other of the surfaces to form an arched, closed-loop magnetic field path over the other surface.

According to embodiments of the present invention, the magnet assembly comprises a plurality of Halbach magnet arrays, each comprising a first, centrally positioned unidirectional magnet with polarity oriented substantially orthogonally away from the one surface of the target; and second and third laterally positioned unidirectional magnets with polarity oriented substantially orthogonally to that of the first magnet and in mutually opposite directions.

In accordance with certain preferred embodiments of the present invention, the plurality of Halbach magnet arrays form a linear arrangement and the magnet assembly further comprises a magnet array at each end of the linear arrangement for forming the closed-loop magnetic field path over the other surface; and each of the magnet arrays at the ends comprises a centrally positioned unidirectional magnet with polarity oriented substantially orthogonally to that of the first magnet and toward a respective lateral end of the target, and a pair of laterally positioned unidirectional magnets, each with polarity oriented at an angle with respect to that of the centrally positioned unidirectional magnet.

Preferred embodiments of the present invention include those wherein the target is flat planar-shaped or hollow cylinder-shaped with inner and outer surfaces. In the latter instance, the magnet assembly is preferably stationary, the target is rotatable about a central axis, and the magnet assembly is positioned adjacent the inner surface.

Further embodiments of the present invention include those wherein the plurality of Halbach magnet arrays form a circular-shaped arrangement; the target is hollow cylinder-shaped with inner and outer surfaces and the magnet assembly is positioned adjacent the outer surface; or alternatively, the magnet assembly is positioned adjacent the inner surface.

Another aspect of the present invention is an improved method of performing magnetron sputtering of at least one target material, comprising steps of:

(a) providing a target comprising at least one material to be sputtered, the target including a pair of oppositely facing surfaces;

(b) providing a magnet assembly comprising a plurality of Halbach magnet arrays adjacent one of the surfaces for providing magnetic field lines which emerge from an re-enter the other of the surfaces to form an arched, closed-loop magnetic field path over the other surface; and

(c) generating a plasma of ionized gas between the target as a cathode electrode and an anode electrode.

According to embodiments of the present invention, step (b) comprises providing a magnet assembly wherein each of the plurality of Halbach magnet arrays comprises a first, centrally positioned unidirectional magnet with polarity oriented substantially orthogonally away from the one surface, and second and third laterally positioned unidirectional magnets with polarity oriented substantially orthogonally to that of the first magnet and in mutually opposite directions.

In accordance with embodiments of the present invention, step (b) comprises providing a magnet assembly wherein the plurality of Halbach magnet arrays form a linear arrangement and the magnet assembly further comprises a magnet array at each end of the linear arrangement for forming the closed-loop magnetic field path over the other surface.

Preferably, step (b) comprises providing a magnet assembly wherein each of the magnet arrays at the ends comprises a centrally positioned unidirectional magnet with polarity oriented substantially orthogonally to that of the first magnet and toward a respective lateral end of the target; and a pair of laterally positioned unidirectional magnets, each with polarity oriented at an angle with respect to that of the centrally positioned unidirectional magnet.

Preferred embodiments of the present invention include those wherein step (a) comprises providing a flat, planar-shaped target or a hollow cylinder-shaped target with inner and outer surfaces. In the latter instance, preferred embodiments of the present invention include those wherein step (a) comprises providing a target rotatable about a central axis; and step (b) comprises providing a stationary magnet assembly, with the magnet assembly adjacent said inner surface.

Further embodiments of the present invention include those wherein step (b) comprises providing a magnet assembly wherein the plurality of Halbach magnet arrays form a circular-shaped arrangement; and step (a) comprises providing a hollow cylinder-shaped target with inner and outer surfaces. Step (b) then alternatively comprises providing the magnet assembly adjacent the outer surface or adjacent the inner surface of the target.

According to preferred embodiments of the present invention, step (a) comprises providing a target comprised of at least one magnetic material, carbon material, or metal material.

Additional advantages and aspects of the present disclosure will become readily apparent to those skilled in the art from the following detailed description, wherein embodiments of the present invention are shown and described, simply by way of illustration of the best mode contemplated for practicing the present invention. As will be described, the present invention is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiments of the present invention can best be understood when read in conjunction with the following drawings, in which the same or similar reference numerals are employed throughout for designating the same or similar features, and wherein the various features are not necessarily drawn to scale but rather are drawn as to best illustrate the pertinent features, wherein:

FIG. 1 is a simplified, schematic perspective view, of a sectioned portion of a conventional planar magnetron sputtering cathode assembly;

FIG. 2 is a simplified, schematic perspective view of the planar magnetron sputtering cathode assembly of FIG. 1 illustrating the racetrack configuration of the magnetic field lines over the target surface;

FIG. 3 is a simplified, schematic cross-sectional view of a portion of conventional cylindrical magnetron sputtering cathode assembly;

FIG. 4 is a perspective view of a portion of a linearly extended Halbach magnet array;

FIG. 5 shows simplified, schematic cross-sectional views of magnet arrangements for aiding in conceptualization of the resultant magnetic flux fields afforded by a Halbach magnet array;

FIG. 6 illustrates, in schematic, cross-sectional view, a linearly extended Halbach magnet array including a plurality of magnet groupings providing magnetic flux cancellation below the lower side of the structure and magnetic flux augmentation above the upper side of the structure;

FIG. 7 illustrates, in schematic, cross-sectional views, several configurations of Halbach cylinders for providing magnetic flux fields confined entirely within the cylinder with zero magnetic flux field exterior of the cylinder;

FIG. 8 shows, in simplified, schematic perspective view, a sectioned portion of a planar magnetron sputtering cathode assembly equipped with an assembly of Halbach magnet arrays according to an illustrative, but non-limitative, embodiment of the present invention; and

FIG. 9 shows, in simplified, schematic cross-sectional view, a portion of a cylindrical magnetron sputtering cathode assembly equipped with an assembly of Halbach magnet arrays according to an illustrative, but non-limitative, embodiment of the present invention.

### DESCRIPTION OF THE INVENTION

The present invention addresses and effectively solves, or at least mitigates, the aforementioned drawbacks and disadvantages associated with conventional magnetron sputtering targets/cathode assemblies arising from the situation where only about one-half of the available magnetic flux passes through and over the target surface for use in plasma and ion generation.

The present invention is based upon recognition that certain unidirectionally polarized magnet arrays, known as “Halbach” arrays, are capable of providing magnetic fields which emerge from and re-enter sputtering targets to provide the arched, closed-loop magnetic field paths characteristic of conventional magnetron magnet assemblies, without the loss of approximately one-half of the magnetic flux as occurs with conventional magnetron magnet assemblies.

As utilized in the following description and appended claims, the term “Halbach magnet array” is to be construed as defining an arrangement (i.e., an array) of permanent magnets which augments the magnetic field at one side, end, or edge of the array while canceling or reducing the magnetic field at the other side, end, or edge of the array to substantially zero.

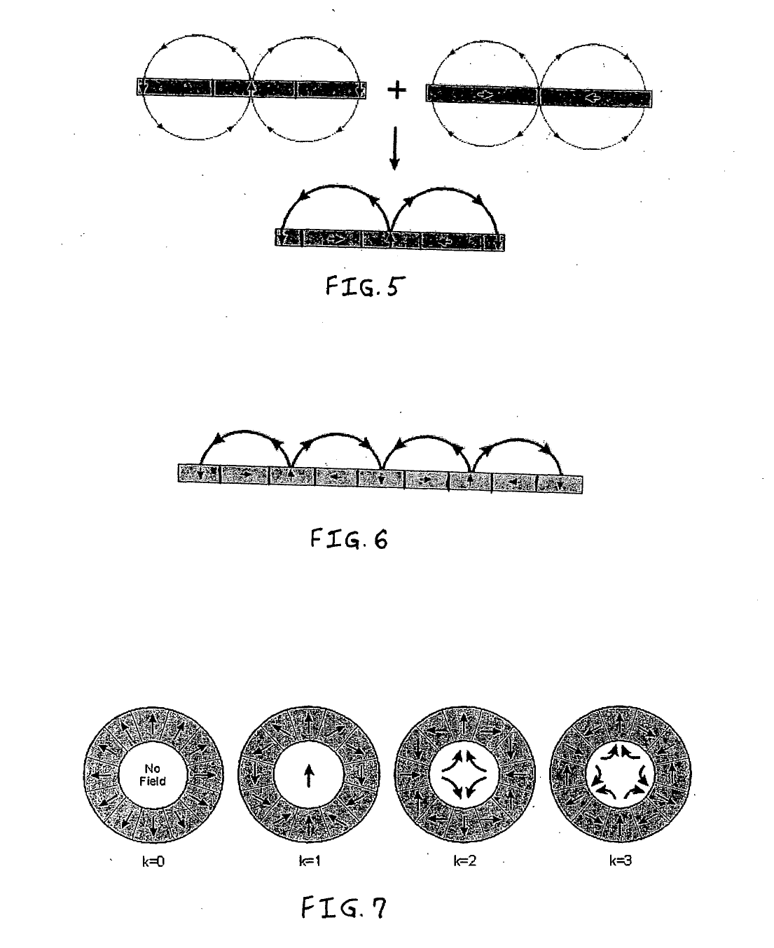

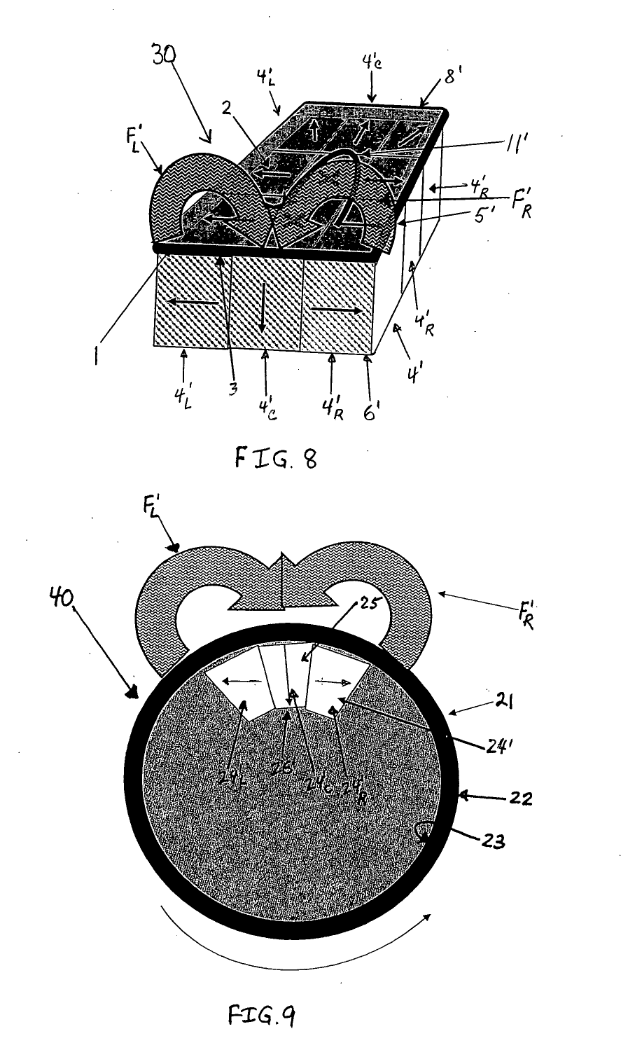

Referring to FIG. 4, shown therein is a perspective view of a portion of a linearly extended Halbach magnet array comprised of a plurality of unidirectionally polarized permanent magnets for providing a one-sided magnetic flux, wherein the magnetic flux field provided by the array, as indicated by the arrow in the figure, is enhanced (i.e., augmented) at the bottom side of the array and cancelled (i.e., reduced) to substantially zero at the top side of the array. In the figure, the polarity orientation of each of the permanent magnets is indicated by the arrows within the magnets, and Θ=magnet end indicated by the head of the arrow and X=magnet end indicated by the tail of the arrow.

The polarity pattern of the permanent magnets, as seen from the arrows on front face of the array, i.e., left (←), up (↑), right (→), down (↓) can be continued indefinitely to the same effect, and is roughly similar to the situation where a plurality of horseshoe-shaped permanent magnets are placed adjacent to each other with alternating polarity. The effect of such “one-sided flux” structures was discovered by Mallinson in 1973, and in the 1980's was utilized by Halbach for focusing of accelerator particle beams.

The magnetic flux distribution provided by the array of FIG. 4 may be better visualized and understood by reference to the diagram of FIG. 5, wherein the top left view shows the magnetic flux field in the y direction provided by a first structure comprised of a group (i.e., 3) of linearly arranged, alternating polarity permanent magnets and the top right view shows the magnetic flux field in the x direction provided by a second structure comprised of a group (i.e., 2) of linearly arranged, opposite polarity permanent magnets. The lower view shows the resultant structure and magnetic flux field when the first and-second structures are combined, as in the structure shown in FIG. 4. It is important to recognize that, while the magnetic flux field above the upper side of the magnets is in the same direction in both instances, the magnetic flux field below the lower side of the magnets is in opposite directions. The effect of superimposing both structures is shown in the lower view of FIG. 5 and demonstrates that the magnetic flux fields from the component structures are cancelled below the lower side of the combined structure and reinforced (augmented) above the upper side of the combined structure. FIG. 6 is similar to FIG. 5 and illustrates the situation where the magnet assembly is extended to include additional Halbach arrays providing magnetic flux cancellation below the lower side of the structure and magnetic flux augmentation above the upper side of the structure.

In this regard, it should be noted that a one-sided magnetic flux field will result in any pattern of magnets wherein the component magnets are □/2 out of phase with each other. Advantages of one-sided flux distributions are twofold:

1. the magnetic flux field at the augmented side of the structure or array is twice as large as that on the opposite side of the structure; and

2. no stray field is produced on the opposite side of the structure, thereby facilitating field confinement.

Halbach arrays can also be formed into cylindrical shaped assemblies, as for example, by utilizing a structure comprised of a plurality of arcuate wedge-shaped permanent magnet segments each with unidirectional magnetic polarization. Referring to FIG. 7, illustrated therein in schematic cross-sectional views, are several configurations of Halbach cylinders in which the resultant magnetic flux field(s) is (are) confined substantially entirely within the cylinder with substantially zero magnetic flux field exterior of the cylinder. The k=2 and k=3 arrangements are well suited for sputtering the interior surface of cylindrical targets coaxially located within the Halbach cylinder. Halbach cylinders comprising a plurality of arcuate wedge-shaped permanent magnet segments with unidirectional magnetic polarization in a direction opposite to that of FIG. 7 can also be fabricated such that the resultant magnetic flux field(s) is (are) confined substantially entirely outside the cylinder with substantially zero magnetic flux field interiorly of the cylinder. Such arrangements are well suited for sputtering the exterior surface of cylindrical targets coaxially located around the Halbach cylinder.

Adverting to FIG. 8, shown therein, in simplified, schematic perspective view, is a sectioned portion of a planar magnetron sputtering cathode assembly equipped with a Halbach magnet assembly 30 according to an illustrative, but non-limitative, embodiment of the present invention. As illustrated, Halbach magnet-equipped planar magnetron sputtering cathode assembly 30 comprises an elongated planar sputtering target 1 with an upper, sputtering surface 2 and a lower surface 3, a Halbach magnet assembly 4′ having an upper end 5′ adjacent the lower surface 3 of target 1, and a lower end 6′. Reference numeral 8′ indicates a first lateral end of assembly 30 and reference numeral 9′ indicates a sectioned end of assembly 30. Not shown in the figure is the second lateral end of assembly 30, similar in essential respect to first lateral end 8′. Also not shown in the figure (for illustrative simplicity) is conventional structure for mounting and maintaining target 1 in fixed position relative to Halbach magnet assembly 4′, e.g., an underlying mounting plate and/or edge-mounted brackets and flanges.

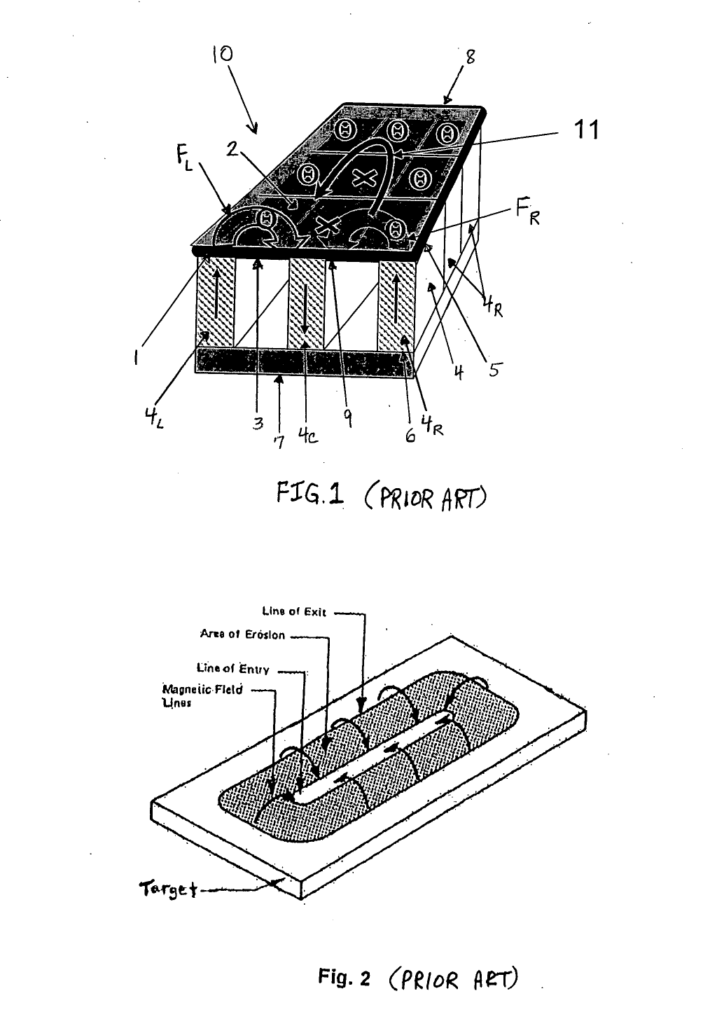

As shown, magnet assembly 4′ comprises a plurality of Halbach magnet arrays wherein unidirectionally polarized magnets are arranged in substantially linear fashion in two dimensions, the magnets having various polarity orientations with respect to sputtering target 1, as indicated by the arrows for each magnet. At portions of assembly 30 other than the first and second lateral ends, e.g., the portion adjacent to sectioned end 9′ of assembly 30 and portions extending toward first lateral end 8′, magnet assembly 4′ comprises a plurality of centrally positioned unidirectional magnets 4′_{C} with substantially downwardly oriented polarity, as indicated by X in the figure, and left and right laterally positioned unidirectional magnets 4′_{L} and 4′_{R}, with polarity oriented substantially orthogonally to the central magnets 4′_{C}, i.e., with leftward (←) and rightward (→) oriented polarity, respectively. As shown by the heavy arrows F′_{L} and F′_{R} in the figure for the set of magnets adjacent sectioned end 9′, a substantially strengthened (augmented) magnetic flux (vis-à-vis magnetic flux F_{L} and F_{R} in the conventional planar magnetron target assembly 10 shown in FIG. 1) from the laterally positioned magnets 4′_{L} and 4′_{R} emerges from target 1 proximate the lateral edges thereof, arches over the upper, sputtering surface 2 of the target, and re-enters the target at the central portion thereof via the centrally positioned magnets 4′_{C}. A similar flux pattern (not shown in the figure for illustrative simplicity) results for each of the other sets of magnets, except for the magnet set at the first lateral end 8′. At the first and second lateral ends of assembly 30, e.g., as illustrated at first lateral end 8′, magnet assembly 4′ comprises a centrally positioned unidirectional magnet 4′_{C} with polarity oriented substantially orthogonally to that of the other central magnets 4′_{C} and a pair of laterally positioned unidirectional magnets 4′_{L} and 4′_{R}, each with angularly outward oriented polarity for providing 180° redirection of electrons confined to the arched flux regions, as shown by arrow 11′, thereby forming the characteristic oval-shaped “racetrack” of planar magnetron target/cathode assemblies, as for example, schematically shown in perspective in FIG. 2.

Referring to FIG. 9, shown therein, in simplified, schematic cross-sectional view, is a portion of conventional cylindrical magnetron sputtering cathode assembly 40 comprising an elongated cylindrical-shaped sputtering target 21 with an outer, sputtering surface 22 and an inner surface 23, a Halbach magnet assembly 24′ positioned adjacent inner surface 22 and having an upper end 25 adjacent the inner surface 23 of target 21, and a lower end 26′. Halbach magnet assembly 24′ comprises a linearly arranged plurality of Halbach magnet arrays each including a centrally positioned unidirectional magnet 24′_{C} with substantially downwardly oriented polarity and a pair of left and right laterally positioned unidirectional magnets 24′_{L} and 24′_{R} with polarities oriented substantially orthogonally to that of central magnet 24′_{C}, i.e., with leftward (←) and rightward (→) oriented polarity, respectively, as shown by the arrows in the figure. Not shown in the figure, for illustrative simplicity, is conventional structure for mounting and rotating cylindrical target 21.

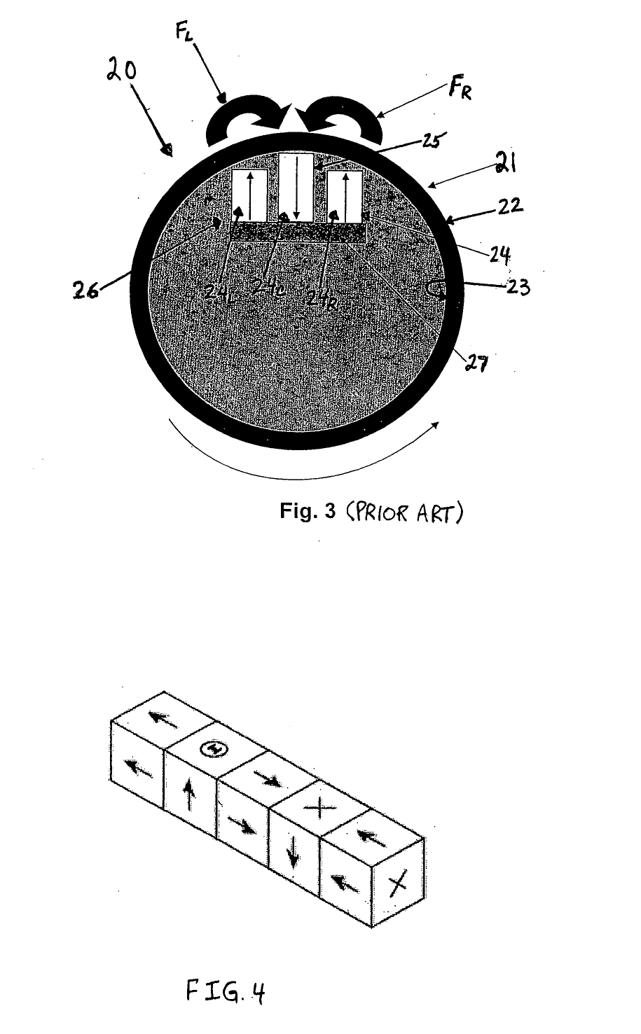

As shown by the heavy arrows F′_{L} and F′_{R} in the figure, a substantially strengthened (augmented) magnetic flux (vis-à-vis magnetic flux F_{L} and F_{R} in the conventional cylindrical magnetron target assembly 20 shown in FIG. 3) emerges from target 21, arches over the outer, sputtering surface 22 of the cylindrically shaped target, and re-enters the target at the central portion thereof via centrally positioned magnet 24′_{C}. As with magnet assembly 4′ of the Halbach magnet equipped planar magnetron sputtering cathode assembly 30 of FIG. 8, magnet assembly 24′ is provided at the lateral ends thereof with a centrally positioned unidirectional magnet 24′_{C} with polarity oriented substantially orthogonally to that of central magnet 24′_{C} and a pair of laterally positioned magnets 24′_{L} and 24′_{R}, each with polarity oriented for providing 180° redirection of electrons confined to the arched flux regions.

As with the conventional cylindrical magnetron sputtering target assembly of FIG. 3, during operation of the Halbach magnet array-equipped cylindrical magnetron sputtering cathode assembly 40, magnet assembly 24′ is maintained stationary while the cylindrical sputtering target 21 is rotated about its axis, thereby facilitating substantially full utilization (i.e., erosion by sputtering) of the entire sputtering surface 22.

The enhanced magnetic flux intensity provided by the Halbach magnet assemblies according to the present invention afford a number of significant advantages vis-à-vis conventionally structured magnet assemblies utilized in magnetron sputtering and eliminate, or at least substantially mitigate several problems and drawbacks associated with sputter deposition of certain target materials, as follows:

1. Halbach magnet array-equipped magnetron sputtering cathodes are capable of utilizing targets of soft magnetic material which are substantially thicker than possible with conventional magnetron cathodes in view of the enhanced emergent magnetic flux densities over the target surface.

2. the sputtering process can be performed at lower pressures, thereby facilitating formation of very high quality deposited films, e.g., carbon films utilized as protective overcoats in thin film magnetic and magneto-optical (MO) recording media; and

3. in reactive sputtering of metal targets, arcing arising from compound formation on the target surface can be better suppressed because the ion flux impinging the target surface is denser, thereby facilitating removal of any surface compounds which form when the target surface of the Halbach magnet array-equipped cylindrical magnetron rotates out of the intense discharge region.

In the previous description, numerous specific details are set forth, such as specific materials, structures, reactants, processes, etc., in order to provide a better understanding of the present invention. However, the present invention can be practiced without resorting to the details specifically set forth. In other instances, well-known processing materials and techniques have not been described in detail in order not to unnecessarily obscure the present invention.

Only the preferred embodiments of the present invention and but a few examples of its versatility are shown and described in the present disclosure. It is to be understood that the present invention is capable of use in other combinations and environments and is susceptible of changes and/or modifications within the scope of the inventive concept as expressed herein.

What is claimed is:

1. A magnetron sputtering target assembly, comprising:
(a) a target adapted to comprise at least one material to be sputtered, said target including a pair of oppositely facing surfaces; and
(b) a magnet assembly comprising a plurality of Halbach magnet arrays adjacent one of said surfaces for providing magnetic field lines which emerge from and re-enter the other of said surfaces to form an arched, closed-loop magnetic field path over said other surface.

2. The target assembly as in claim 1, wherein said magnet assembly comprises a plurality of Halbach magnet arrays, each comprising:
i. a first, centrally positioned unidirectional magnet with polarity oriented substantially orthogonally away from said one of said surfaces of said target; and
ii. second and third laterally positioned unidirectional magnets with polarity oriented substantially orthogonally to that of said first magnet and in mutually opposite directions.

3. The target assembly as in claim 2, wherein:
said plurality of Halbach magnet arrays form a linear arrangement and said magnet assembly further comprises a magnet array at each end of said linear arrangement for forming said closed-loop magnetic field path over said other surface.

4. The target assembly as in claim 3, wherein each of said magnet arrays at said ends comprises:
i. a centrally positioned unidirectional magnet with polarity oriented substantially orthogonally to that of said first magnet and toward a respective lateral end of said target; and
ii. a pair of laterally positioned unidirectional magnets, each with polarity oriented at an angle with respect to that of said centrally positioned unidirectional magnet.

5. The target assembly as in claim 3, wherein said target is flat planar-shaped.

6. The target assembly as in claim 3, wherein said target is hollow cylinder-shaped with inner and outer surfaces.

7. The target assembly as in claim 6, wherein said magnet assembly is stationary and said target is rotatable about a central axis.

8. The target assembly as in claim 6, wherein said magnet assembly is positioned adjacent said inner surface.

9. The target assembly as in claim 2, wherein said plurality of Halbach magnet arrays form a circular-shaped arrangement.

10. The target assembly as in claim 9, wherein said target is hollow cylinder-shaped with inner and outer surfaces and said magnet assembly is positioned adjacent said outer surface.

11. The target assembly as in claim 9, wherein said target is hollow cylinder-shaped with inner and outer surfaces and said magnet assembly is positioned adjacent said inner surface.

12. A method of performing magnetron sputtering of at least one target material, comprising steps of:
(a) providing a target comprising at least one material to be sputtered, said target including a pair of oppositely facing surfaces;
(b) providing a magnet assembly comprising a plurality of Halbach magnet arrays adjacent one of said surfaces for providing magnetic field lines which emerge from and re-enter the other of said surfaces to form an arched, closed-loop magnetic field path over said other surface; and
(c) generating a plasma of ionized gas between said target as a cathode electrode and an anode electrode.

13. The method according to claim 12, wherein:
step (b) comprises providing a magnet assembly wherein each of said plurality of Halbach magnet arrays comprises a first, centrally positioned unidirectional magnet with polarity oriented substantially orthogonally away from said one of said surfaces of said target, and second and third laterally positioned unidirectional magnets with polarity oriented substantially orthogonally to that of said first magnet and in mutually opposite directions.

14. The method according to claim 13, wherein:
step (b) comprises providing a magnet assembly wherein said plurality of Halbach magnet arrays form a linear arrangement and said magnet assembly further comprises a magnet array at each end of said linear arrangement for forming said closed-loop magnetic field path over said other surface.

15. The method according to claim 14, wherein:
step (b) comprises providing a magnet assembly wherein each of said magnet arrays at said ends comprises a centrally positioned unidirectional magnet with polarity oriented substantially orthogonally to that of said first magnet and toward a respective lateral end of said target; and a pair of laterally positioned unidirectional magnets, each with polarity oriented at an angle with respect to that of said centrally positioned unidirectional magnet.

16. The method according to claim 14, wherein:
step (a) comprises providing a flat, planar-shaped target.

17. The method according to claim 14, wherein:
step (a) comprises providing a hollow cylinder-shaped target with inner and outer surfaces.

18. The method according to claim 17, wherein:
step (a) comprises providing a target rotatable about a central axis; and step (b) comprises providing a stationary magnet assembly.

19. The method according to claim 17, wherein:
step (b) comprises providing said magnet assembly adjacent said inner surface.

20. The method according to claim 12, wherein:
step (b) comprises providing a magnet assembly wherein said plurality of Halbach magnet arrays form a circular-shaped arrangement.

21. The method according to claim 20, wherein:
step (a) comprises providing a hollow cylinder-shaped target with inner and outer surfaces; and
step (b) comprises providing said magnet assembly adjacent said outer surface.

22. The method according to claim 20, wherein:
step (a) comprises providing a hollow cylinder-shaped target with inner and outer surfaces; and
step (b) comprises providing said magnet assembly adjacent said inner surface.

23. The method according to claim 12, wherein:
step (a) comprises providing a target comprised of at least one magnetic material, carbon material, or metal material.
